(19) United States
(12) Patent Application Publication
(10) Pub. No.: US 2013/0241058 A1
(43) Pub. Date: Sep. 19, 2013

(54) Wire Bonding Structures for Integrated Circuits

(71) Applicants: Chen-Hua Yu, Hsin-Chu (TW); Mirng-Ji Lii, Sinpu Township (TW); Chien-Hsiun Lee, Chu-Tung Town (TW); Yung Ching Chen, Dali City (TW)

(72) Inventors: Chen-Hua Yu, Hsin-Chu (TW); Mirng-Ji Lii, Sinpu Township (TW); Chien-Hsiun Lee, Chu-Tung Town (TW); Yung Ching Chen, Dali City (TW)

(73) Assignee: Taiwan Semiconductor Manufacturing Company, Ltd., Hsin-Chu (TW)

(21) Appl. No.: 13/422,306

(22) Filed: Mar. 16, 2012

(51) Int. Cl. H01L 23/48

(52) U.S. Cl. 257/738; 257/E23.021

(57) ABSTRACT

A device includes a substrate, and a bond pad over the substrate. A protection layer is disposed over the bond pad. The protection layer and the bond pad include different materials. A bond ball is disposed onto the protection layer. A bond wire is joined to the bond ball.

### BACKGROUND

Integrated Circuit (IC) chips are often electrically connected by wires (e.g., gold wires or copper wires) to a package substrate in a packaging assembly to provide external signal exchange. Such wires are typically bonded to the bond pads formed on an IC chips using thermal compression and/or ultrasonic vibration. Wire bonding processes exert thermal and mechanical stresses. The stresses are applied on the bond pads, and imparted to the underlying layers and structures that are located below the bond pads. The structures of the bond pads need to be able to sustain the stresses to ensure a quality bonding of the wires.

Currently, many processes use low-k and ultra-low-k dielectric materials in the Inter-Metal Dielectric (IMD) layers to reduce RC delay and parasitic capacitances. The general trend in the IMD design is that the dielectric constants (k values) of the IMD layers tend to decrease from low-k regime to ultra-low-k regime. This means that the IMD layers, in which metal lines and vias are formed, are more mechanically fragile. Furthermore, the IMD layers may delaminate when under the stress applied by the wire bonding force. The yield of the bonding processes is thus adversely affected.

### BRIEF DESCRIPTION OF THE DRAWINGS

For a more complete understanding of the embodiments, and the advantages thereof, reference is now made to the following descriptions taken in conjunction with the accompanying drawings, in which:

FIG. 1 is a cross-sectional view of a die in accordance with some exemplary embodiments, wherein the die includes a wire bonding structure, which includes a bond pad and a protection layer on the bond pad; and

FIGS. 2 through 4 are cross-sectional views of dies in accordance with alternative embodiments.

### DETAILED DESCRIPTION OF ILLUSTRATIVE EMBODIMENTS

The making and using of the embodiments of the disclosure are discussed in detail below. It should be appreciated, however, that the embodiments provide many applicable inventive concepts that can be embodied in a wide variety of specific contexts. The specific embodiments discussed are illustrative, and do not limit the scope of the disclosure.

Wire bond structures are provided in accordance with various exemplary embodiments. The variations of the embodiments are discussed. Throughout the various views and illustrative embodiments, like reference numbers are used to designate like elements.

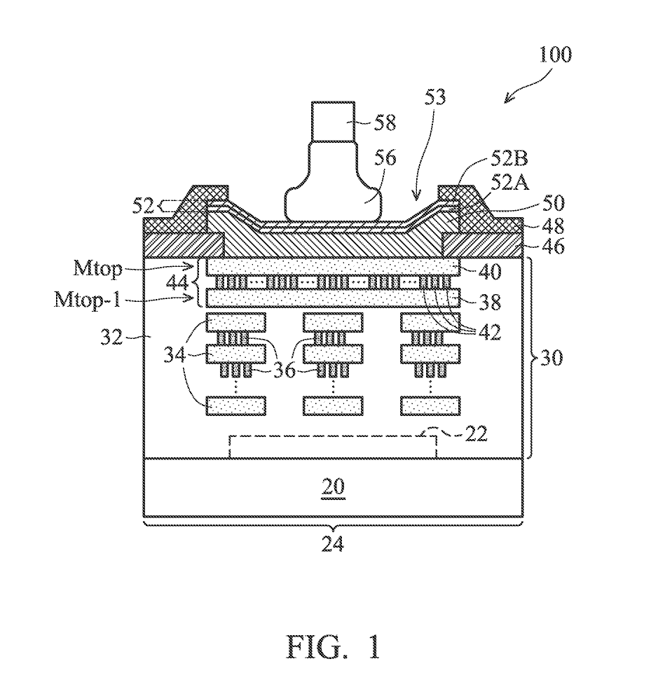

FIG. 1 illustrates a cross-sectional view of die 100 in accordance with some embodiments. Die 100 includes substrate 20, and active circuit 22 formed at a top surface of substrate 20. In some embodiments, substrate 20 is a semiconductor substrate, which may be formed of silicon, silicon germanium, or the like. Active circuit 22 may include Complementary Metal-Oxide-Semiconductor (CMOS) transistors, resistors, capacitors, and the like. The illustrated region 24 of die 100 may be an Input/Output (IO) region. Accordingly, active circuit 22 may be an IO circuit. In alternative embodiments, no active circuit is formed in the illustrate region 24. The active circuits, however, may still be formed in other regions of die 100.

Interconnect structure 30 is formed in region 24, and includes a portion over and aligned to active circuit 22. Interconnect structure 30 includes metal lines 34 and vias 36, which are used to interconnect different portions of active circuit 22, and to connect active circuit 22 to overlying bond pad 50. Interconnect structure 30 includes dielectric layers 32, in which metal lines 34 and vias 36 are formed. Throughout the description, the metal lines 34 that are at a same level are collectively referred to as a metal layer. In some embodiments, dielectric layers 32 are low-k dielectric layers, which may have dielectric constants (k values) lower than about 3.0, or between about 2.0 and 2.8. Metal lines 34 and vias 36 may be formed of copper or copper alloys. In some embodiments, metal lines 34 and vias 36 have electrical connecting functions, and may have currents/signals flowing through. In alternative embodiments, metal lines 34 and vias 36 are dummy connections that are not used as electrical connections. Accordingly, when die 100 is powered up, dummy metal lines 34 and vias 36 have no current flowing through them.

Interconnect structure 30 includes top dielectric layers, in which metal pads 38 and 40 are formed, and the top dielectric layers may be formed of un-doped silicate glass or low-k dielectric materials. In some embodiments, in the two top metal layers of interconnect structure 30, which are referred to as layers Mtop and Mtop-1, double solid pad 44 is formed. Double solid pad 44 includes Mtop pad 40, Mtop-1 pad 38, and a plurality of vias 42 connecting pads 40 and 38. Mtop pad 40, Mtop-1 pad 38, and vias 42 may be formed of copper, tungsten, or other metals, and may be formed using dual damascene or single damascene processes. Alternatively, Mtop pad 40 and Mtop-1 pad 38 may be formed by depositing metal layers, and etching the metal layers.

In some embodiments, double solid pad 44 is in physical contact with the overlying bond pad 50. In alternative embodiments, double solid pad 44 may be electrically connected to bond pad 50 through vias (not shown). In yet alternative embodiments, instead of forming double solid pad 44, a single pad, which is located in Mtop layer, may be formed underlying bond pad 50.

Passivation layers 46 and 48 are formed over substrate 20, and also over interconnect structure 30. Passivation layers 46 and 48 are referred to in the art as passivation-1 and passivation-2, respectively, and may be formed of materials such as silicon oxide, silicon nitride, un-doped silicate glass (USG), and/or multi-layers thereof. In some embodiments, bond pad 50 is formed at the same level as a portion of passivation layer 46. The edge portions of bond pad 50 may be formed over and aligned to the portion of passivation layer 46. Furthermore, bond pad 50 may include a portion in passivation layer 48 and exposed through opening 53 in passivation layer 48. Some edge portions of bond pad 50 may be covered by portions of passivation layer 48. Bond pad 50 may be formed of a metallic material such as aluminum, copper, silver, gold, nickel, tungsten, alloys thereof, and/or multi-layers thereof. In some embodiments, bond pad 50 is formed of aluminum copper. The volume percentages of aluminum and copper in bond pad 50 may be about 99.5 percent and about 0.5 percent, respectively in some exemplary embodiments. In other exemplary embodiments, bond pad 50 includes aluminum, silicon, and copper. The volume percentages of aluminum, silicon, and copper in the silicon-containing aluminum copper may be about 97.5 percent, about 2 percent, and about 0.5 percent, respectively. Bond pad 50 may be electrically coupled to active circuit 22, for example, through double solid pad 44 or other interconnections. The thickness of bond pad 50 may be between about 5 kÅ and about 40 kÅ, for example.

Protection layer 52 is formed over the top surface of bond pad 50. Protection layer 52 may be a single layer, or may be a composite layer comprising a plurality of layers. In some embodiments, protection layer 52 includes gold layer 52A and nickel layer 52B over gold layer 52A. Gold layer 52A may be in contact with bond pad 50. Protection layer 52 may be an Electroless Nickel Immersion Gold (ENIG), which is formed of immersion. In alternative embodiments, protection layer may include Electroless Nickel Electroless Palladium Immersion Gold (ENEPIG), which includes a gold layer over bond pad 50, a palladium layer over the gold layer, and a nickel layer over the palladium layer. The formation methods of protection layer 52 include electro plating, electroless plating, immersion, Physical Vapor Deposition (PVD), and combinations thereof. The hardness of protection layer 52 may be greater than the hardness of bond pad 50.

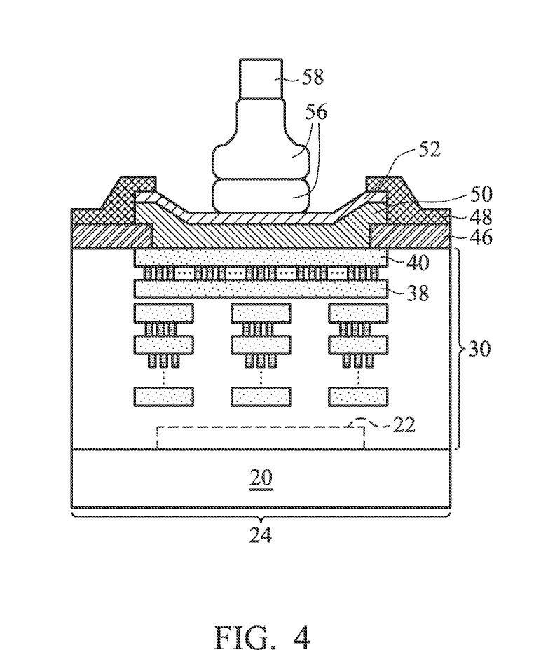

During the wire bonding process of die 100, a wire bond is made to electrically connect die 100 to another package component (not shown), for example, a package substrate, a lead frame, or the like. The bonding is made through wire bonding to bond pad 50. The respective wire bond includes bond ball 56 (also known as a bump stud in the art) and the connecting wire 58, wherein bond ball 56 has a greater diameter than wire 58. Bond ball 56 and wire 58 may be formed of gold, copper, aluminum, and/or the like. Through bond ball 56, bond wire 58 is electrically connected to bond pad 50, and further to the underlying active circuit 22. The wire bonding may be a forward wire bonding, a reverse wire bonding, a stacked-bump bonding (for example, in FIG. 4), or the like. Wire 58 may have a diameter between about 0.5 mil and about 2.0 mil.

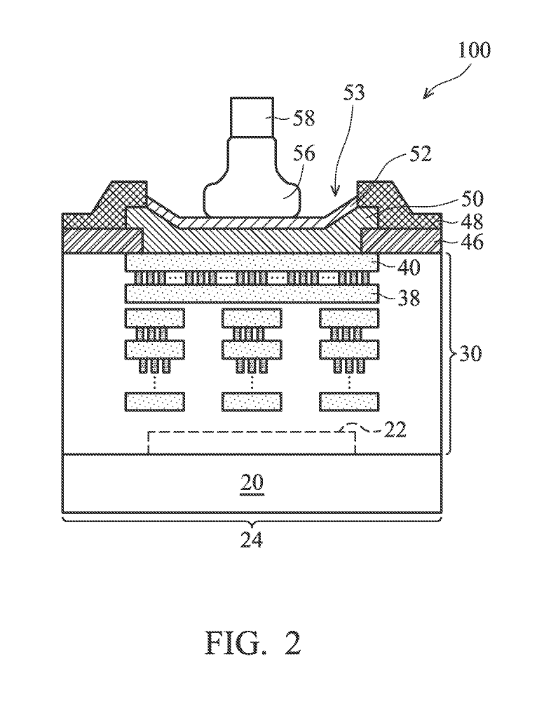

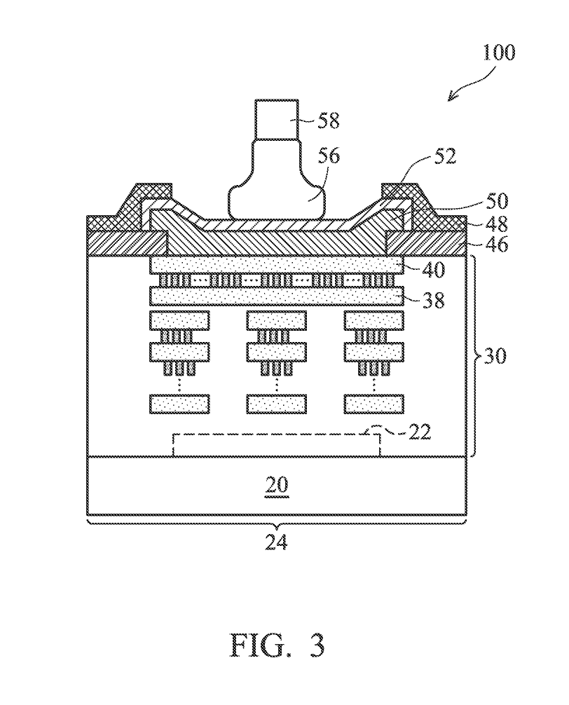

Protection layer 52 may have various forms in accordance with various embodiments. Referring to FIG. 1, protection layer 52 is formed over and aligned to an entirety of the top surface of bond pad 50. In alternative embodiments, as shown in FIG. 2, protection layer 52 is formed in opening 53 of passivation layer 48, and does not extend underlying passivation layer 48. In yet other embodiments, as shown in FIG. 3, protection layer 52 is formed over and aligned to an entirety of the top surface of bond pad 50, and further extends onto the sidewalls of bond pad 50. Protection layer 52 in these embodiments also extends underlying and overlapping portions of passivation layer 48.

In the embodiments, protection layer 52 may have a greater hardness than bond pad 50, and hence may help spread the stress that is generated in the bonding process to a larger chip area. Without the protection layer, bond pad 50 will impart more stress to the underlying structures such as the low-k dielectric layers. The yield in the wire bonding process is thus improved through the use of the embodiments.

In accordance with embodiments, a device includes a substrate, and a bond pad over the substrate. A protection layer is disposed over the bond pad. The protection layer and the bond pad include different materials. A bond ball is disposed onto the protection layer. A bond wire is joined to the bond ball.

In accordance with other embodiments, a device includes a semiconductor substrate, an aluminum copper pad over the semiconductor substrate, and a first and a second passivation layer. The first passivation layer includes portions underlying edge portions of the aluminum copper pad. The second passivation layer includes portions overlying the edge portions of the aluminum copper pad. A protection layer is disposed over and contacting the aluminum copper pad. The protection layer includes a gold layer, and a nickel layer over the gold layer. A bond ball is bonded to the protection layer. A bond wire is joined to the bond ball, wherein the bond wire is electrically coupled to the aluminum copper pad.

In accordance with yet other embodiments, a device includes a semiconductor substrate, an aluminum copper pad over the semiconductor substrate, and a first and a second passivation layer. The first passivation layer includes portions underlying edge portions of the aluminum copper pad. The second passivation layer includes portions overlying the edge portions of the aluminum copper pad. A protection layer is disposed over the aluminum copper pad. The protection layer has hardness greater than a hardness of the aluminum copper pad. A bond ball is bonded onto the protection layer. A bond wire is attached to the bond ball.

Although the embodiments and their advantages have been described in detail, it should be understood that various changes, substitutions and alterations can be made herein without departing from the spirit and scope of the embodiments as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure, processes, machines, manufacture, compositions of matter, means, methods, or steps, presently existing or later to be developed, that perform substantially the same function or achieve substantially the same result as the corresponding embodiments described herein may be utilized according to the disclosure. Accordingly, the appended claims are intended to include within their scope such processes, machines, manufacture, compositions of matter, means, methods, or steps. In addition, each claim constitutes a separate embodiment, and the combination of various claims and embodiments are within the scope of the disclosure.

1. A device comprising:
a substrate;
a bond pad over the substrate;
a protection layer over the bond pad, wherein the protection layer and the bond pad comprise different materials;
a first passivation layer comprising a portion underlying a portion of the bond pad;
a second passivation layer over the first passivation layer, wherein the second passivation layer covers edge portions of the bond pad;
a bond ball disposed onto and in physical contact with the protection layer; and
a bond wire joined to the bond ball.

2. The device of claim 1, wherein the bond pad comprises aluminum and copper, and wherein the protection layer comprises a gold layer, and a nickel layer over the gold layer.

3. The device of claim 2, wherein the bond ball is in contact with the nickel layer, and wherein the gold layer is in contact with the bond pad.

4.-5. (canceled)

6. The device of claim 1, wherein the protection layer further extends on sidewalls of the bond pad.

7. The device of claim 1, wherein the protection layer is disposed in an opening in the second passivation layer, and is substantially free from portions underlying the second passivation layer.

8. A device comprising:
a semiconductor substrate;
a pad comprising aluminum and copper over the semiconductor substrate;
a first passivation layer comprising portions underlying edge portions of the pad;
a second passivation layer comprising portions overlying the edge portions of the pad;
a protection layer over and contacting the pad, wherein the protection layer comprises a gold layer, and a nickel layer over the gold layer and wherein the protection layer further extends on sidewalls of the pad;
a bond ball bonded to the protection layer; and
a bond wire joined to the bond ball, wherein the bond wire is electrically coupled to the pad.

9. The device of claim 8, wherein the protection layer further comprises a palladium layer between the gold layer and the nickel layer.

10. The device of claim 8, wherein the pad is in an input/output region of a respective die.

11. The device of claim 8, wherein no active circuit is underlying and aligned to the pad.

12. The device of claim 8 further comprises a double solid pad underlying and aligned to the pad.

13. The device of claim 8, wherein the bond ball is in contact with the nickel layer.

14. A device comprising:
a semiconductor substrate;
a pad comprising aluminum and copper over the semiconductor substrate;
a first passivation layer comprising portions underlying edge portions of the pad;
a second passivation layer comprising portions overlying the edge portions of the pad, wherein the second passivation layer is exposed to air;
a protection layer over the pad, wherein the protection layer has a hardness greater than a hardness of the pad;
a bond ball bonded onto the protection layer; and
a bond wire attached to the bond ball.

15. The device of claim 14, wherein the protection layer comprises a gold layer, and a nickel layer over the gold layer.

16. The device of claim 15, wherein the protection layer further comprises a palladium layer between the gold layer and the nickel layer.

17. The device of claim 14, wherein the protection layer is disposed in an opening in the second passivation layer, and is substantially free from portions underlying and aligned to the second passivation layer.

18. The device of claim 14 further comprising a double solid metal pad underlying and connected to the pad.

19. The device of claim 14, wherein the bond ball comprises stacked bumps.

20. The device of claim 14, wherein the bond ball is in physical contact with the protection layer.

21. The device of claim 1, wherein the second passivation layer is exposed to air.

22. The device of claim 8, wherein the second passivation layer is an outmost layer of a respective die that comprises the pad, the first passivation layer, and the second passivation layer.
